(19) United States
(12) Patent Application Publication
(10) Pub. No.: US 2022/0037211 A1
(43) Pub. Date: Feb. 3, 2022

(54) PREPARATION METHOD FOR SEMICONDUCTOR DEVICE

(71) Applicant: CSMC TECHNOLOGIES FAB2 CO., LTD., Wuxi (CN)

(72) Inventor: Yuanbao LIAO, Wuxi (CN)

(21) Appl. No.: 17/299,380

(22) PCT Filed: Dec. 4, 2019
(86) PCT No.: PCT/CN2019/122847

§ 371 Date: Jun. 3, 2021

(30) Foreign Application Priority Data
Dec. 5, 2018 (CN) 201811478102.9

(51) Int. Cl. H01L 21/8234; H01L 27/02

(52) U.S. Cl. CPC H01L 21/823493; H01L 21/823418; H01L 21/823475; H01L 27/0255

(57) ABSTRACT

The present application relates to a preparation method for a semiconductor device, comprising: sequentially forming an isolating dielectric layer and a doped semiconductor layer of a first conductivity type on a non-primitive cell area of a semiconductor substrate; performing a first conductivity type of well injection by using the semiconductor layer and the isolating dielectric layer as masks, and forming a well area in a primitive cell area; forming an operation structure in the well area, and forming a protection structure in the semiconductor layer; and forming an interlayer dielectric layer on the operation structure and the protection structure, forming a contact hole in the interlayer dielectric layer, forming a metal interconnection layer connected to the contact hole on the interlayer dielectric layer, and connecting the operation structure and the protection structure by means of the metal interconnection layer and the contact hole.

### CROSS-REFERENCE TO RELATED APPLICATION

This application claims priority to Chinese Patent Application No. 201811478102.9, entitled “PREPARATION METHOD FOR SEMICONDUCTOR DEVICE”, filed Dec. 5, 2018, the entire content of which is incorporated herein by reference.

### TECHNICAL FIELD

The present disclosure relates to the field of semiconductors, more particularly, to a method for manufacturing a semiconductor device.

### BACKGROUND

Semiconductor device generally includes a work structure and a protection structure protecting the work structure. For example, a metal-oxide-semiconductor field-effect transistor (hereinafter referred to as MOS transistor) may generate static electricity during production, assembly, testing or handling. When an electrostatic voltage is high, the MOS transistor may be damaged, so a diode is generally added as an electrostatic protection structure in parallel with the MOS transistor to protect the MOS transistor. A specific preparation process of a semiconductor device generally includes: forming field oxide in a non-cell region of a semiconductor substrate, performing self-alignment well injection on the semiconductor substrate by using the field oxide as a mask to form a well region in the cell region, depositing a semiconductor layer on the field oxide, doping the semiconductor layer to form a protection structure on the non-cell region, doping the well region to form a work structure in the cell region, and next, depositing an interlayer dielectric layer and forming a contact hole in the interlayer dielectric layer to extract an electrode. To realize self-alignment mask well injection, the field oxide is required to reach a particular thickness, which is set to h1, and the semiconductor layer deposited on the field oxide also has a particular thickness, which is set to h2. That is, on the semiconductor substrate, a surface of the protection structure on the non-cell region is h1+h2 higher than a surface of the work structure in the cell region, while an upper surface of the interlayer dielectric layer is flat, which makes the thickness of the interlayer dielectric layer above the protection structure on the non-cell region h1+h2 smaller than that of the interlayer dielectric layer above the cell region. As a result, the interlayer dielectric layer above the protection structure is thinner. In a subsequent process, such as a process of forming and etching a metal layer, the interlayer dielectric layer above the protection structure is prone to loss, which exposes the protection structure and damages the protection structure.

### SUMMARY

According to various embodiments of the present disclosure, a method for manufacturing a semiconductor device is provided.

A method for manufacturing a semiconductor device is provided, the semiconductor device including a work structure and a protection structure configured to protect the work structure, the manufacturing method includes:

providing a semiconductor substrate comprising a cell region and a non-cell region, forming an isolation dielectric layer on the non-cell region of the semiconductor substrate, and forming a semiconductor layer having a first-conductivity-type doping on the isolation dielectric layer;

performing a first-conductivity-type well implantation to the semiconductor substrate by using the semiconductor layer and the isolation dielectric layer as masks, and forming a well region in the cell region of the semiconductor substrate;

doping the well region to form the work structure in the cell region, and doping the semiconductor layer to form the protection structure on the non-cell region; and

forming an interlayer dielectric layer on the work structure and the protection structure, forming a contact hole in the interlayer dielectric layer, forming a metal interconnection layer connected to the contact hole on the interlayer dielectric layer, the work structure and the protection structure being connected by the metal interconnection layer and the contact hole.

Details of one or more embodiments of the present application are set forth in the following accompanying drawings and descriptions. Other features, objectives, and advantages of the present application become obvious with reference to the specification, the accompanying drawings, and the claims.

### BRIEF DESCRIPTION OF THE DRAWINGS

In order to better describe and illustrate embodiments and/or examples of those applications disclosed herein, reference may be made to one or more accompanying drawings. Additional details or examples used to describe the accompanying drawings should not be considered as limitations on the scope of any of the disclosed applications, the presently described embodiments and/or examples, and the presently understood best mode of these applications.

FIG. 1a to FIG. 1c are state diagrams of devices corresponding to relevant steps of a manufacturing method for a semiconductor device in a conventional technology;

FIG. 2 is a flowchart of a method for manufacturing a semiconductor device according to an embodiment of the present disclosure, and

FIG. 3a to FIG. 3d are state diagrams of devices corresponding to the steps of the method for manufacturing a semiconductor device according to the present disclosure.

### DETAILED DESCRIPTION OF THE EMBODIMENTS

To facilitate the understanding of the present application, a more comprehensive description of the present application is given below with reference to the accompanying drawings. Preferred embodiments of the present application are given in the accompanying drawings. However, the present application may be implemented in many different forms and is not limited to the embodiments described herein. On the contrary, these embodiments are provided to understand the disclosed content of the present application more thoroughly and comprehensively.

Unless otherwise defined, all technical and scientific terms used herein have the same meaning as commonly understood by those of ordinary skill in the art to which the present application belongs. The terms used in the specification of the present application are intended only to describe particular embodiments and are not intended to limit the present application. The term “and/or” used herein includes any and all combinations of one or more of the associated listed items.

In order to fully understand the present application, detailed steps and structures will be provided in the description below to explain the technical solution in the present application. Preferred embodiments of the present application are described in detail below; however, in addition to these detailed descriptions, there may be other embodiments of the present application.

An example of a vertical double-diffusion metal-oxide-semiconductor field-effect transistor (referred hereinafter as VDMOS transistor) connected to a diode is given to illustrate steps of an existing process of manufacturing a semiconductor device. The VDMOS transistor is a work structure, and the diode is an electrostatic protection structure. The manufacture includes the following steps.

In step S110, a semiconductor substrate is provided, which includes a cell region and a non-cell region, and field oxide is formed on the non-cell region.

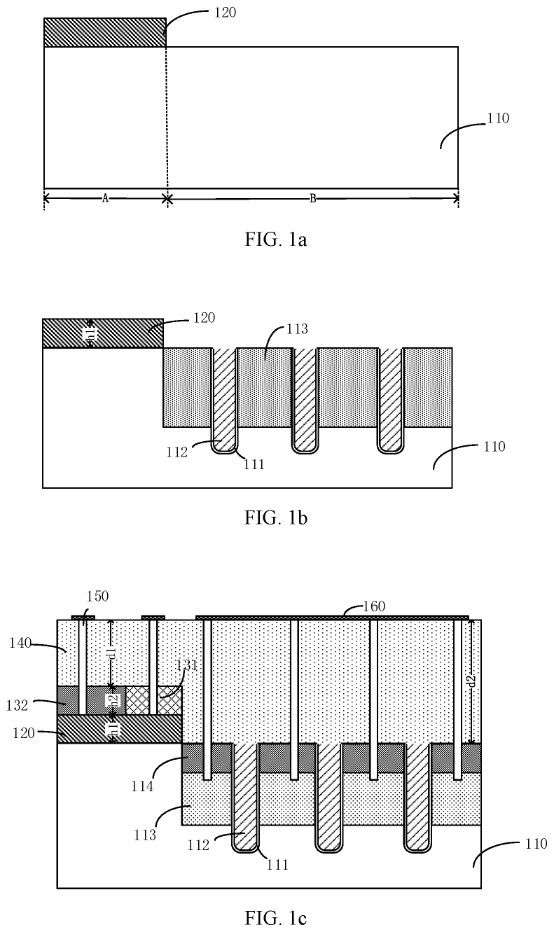

As shown in FIG. 1a, a semiconductor substrate 110 includes a cell region B and a non-cell region A. After a field oxide layer is formed on the semiconductor substrate 110, a field oxide on the cell region is removed by photolithography and etching processes, while a field oxide 120 in the non-cell region A is retained.

In step S120, a trench is formed in the cell region of the semiconductor substrate, a gate oxide layer is formed on an inner wall of the trench, the trench is filled with gate polysilicon, first-conductivity-type well implantation is performed on the semiconductor substrate of the cell region by using the field oxide as a mask, and a well region is formed.

As shown in FIG. 1b, a trench is formed in the semiconductor substrate 110 of the cell region by photolithography and etching processes. A gate oxide layer 111 is formed on an inner wall of the trench, the trench is filled with gate polysilicon 112. Self-alignment well implantation is performed on the semiconductor substrate of the cell region by using the field oxide 120 as a mask, and a well region 113 is formed. The field oxide 120 is required to have a particular height of h1 to serve as a self-alignment mask of well implantation, that is, the field oxide 120 has a thickness of h1.

In step S130, a semiconductor layer is formed on the field oxide. A first-conductivity-type doping is performed on the semiconductor layer to form a first-conductivity-type semiconductor structure. A second-conductivity-type doping is performed on the semiconductor layer to form a second-conductivity-type semiconductor structure. The first-conductivity-type semiconductor structure and the second-conductivity-type semiconductor structure form a PN junction. The second-conductivity-type doping is performed on the well region to form a source region. An interlayer dielectric layer is formed on the semiconductor layer, the trench and the source region, and a contact hole is formed in the interlayer dielectric layer. A first electrode of a diode is extracted from the first-conductivity-type semiconductor structure, and a second electrode of the diode is extracted from the second-conductivity-type semiconductor structure through the contact hole. A gate is extracted from the gate polysilicon. A metal interconnection layer is formed on the interlayer dielectric layer, and the first electrode is connected to the gate and the second electrode is connected to the source through the metal interconnection layer.

As shown in FIG. 1c, a semiconductor layer is deposited on the field oxide 120. The semiconductor layer has a thickness of h2. A first-conductivity-type doping and a second-conductivity-type doping are performed on the semiconductor layer, such that partial semiconductors of the semiconductor layer are of a first conductivity type and partial semiconductors are of a second conductivity type, that is, a first-conductivity-type semiconductor structure 131 and a second-conductivity-type semiconductor structure 132 are formed on the semiconductor layer. The first-conductivity-type semiconductor structure 131 and the second-conductivity-type semiconductor structure 132 form a PN junction. The PN junction forms a diode. At the same time, the second-conductivity-type doping is performed on the well region to form a source region 114. An interlayer dielectric layer 140 covers the source region 114, the trench and the semiconductor layer, and a contact hole 150 is formed in the interlayer dielectric layer 140. Specifically, a contact hole is formed in the interlayer dielectric layer 140 above the first-conductivity-type semiconductor structure 131 to extract the first electrode of the diode. A contact hole is formed in the interlayer dielectric layer 140 above the second-conductivity-type semiconductor structure 132 to extract the second electrode of the diode. A contact hole is formed in the interlayer dielectric layer 140 above the source region 114 to extract a source. A contact hole is formed in the interlayer dielectric layer 140 above the gate polysilicon 112 to extract a gate (not shown in the FIG). A metal interconnection layer 160 is formed on the interlayer dielectric layer 140. The first electrode is connected to the gate and the second electrode is connected to the source through the metal interconnection layer 160, and a drain is formed on a back surface of the semiconductor substrate, thus forming a VDMOS device with diode electrostatic protection.

In the semiconductor device formed by the above semiconductor manufacturing method, the field oxide 120 has a thickness of h1, the semiconductor layer has a thickness of h2, the interlayer dielectric layer 140 above the semiconductor layer has a thickness of d1, the interlayer dielectric layer 140 above the source region 114 has a thickness of d2, and then d2−d1=h1+h2. That is, the thickness of the interlayer dielectric layer above the non-cell region A is h1+h2 thinner than that of the interlayer dielectric layer above the cell region. Since a contact hole is required to be formed in the interlayer dielectric layer, a size of the contact hole is limited by a process line width, such that the thickness of the interlayer dielectric layer above the cell region cannot exceed a particular value, thereby making the interlayer dielectric layer above the non-cell region thinner. In a subsequent process such as a metal etching process, the interlayer dielectric layer may be lost. When the interlayer dielectric layer above the non-cell region is thinner, the interlayer dielectric layer above the non-cell region may be removed in the metal etching process, and the protection structure below the interlayer dielectric layer may be damaged.

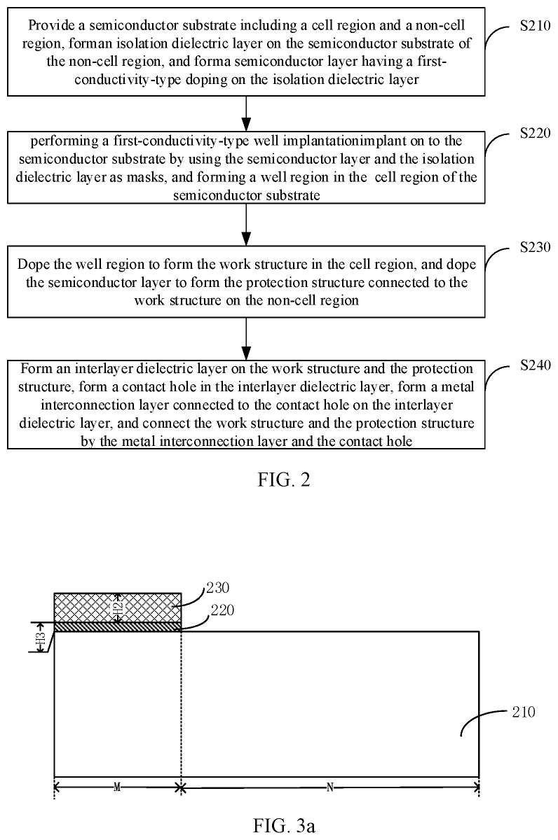

Accordingly, the present solution provides a new method for manufacturing semiconductors, which can increase the thickness of the interlayer dielectric layer on the protection structure. As shown in FIG. 2, the manufacturing method includes the following steps.

In step S210, a semiconductor substrate is provided, which includes a cell region and a non-cell region. An isolation dielectric layer is formed on the non-cell region of the semiconductor substrate, and a semiconductor layer having a first-conductivity-type doping is formed on the isolation dielectric layer.

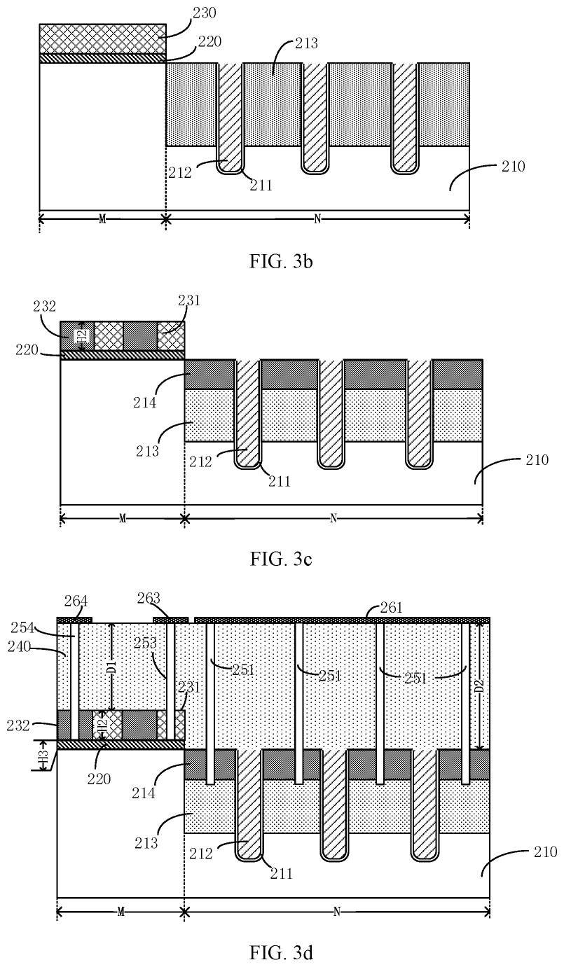

As shown in FIG. 3a, a semiconductor substrate 210 including a cell region N and a non-cell region M is provided. In one embodiment, the cell region N is located at a center position of the semiconductor substrate 210, and the non-cell region M is located on a periphery of the semiconductor substrate 210 and surrounds the cell region N, thereby isolating the structure in the cell region. An isolation dielectric layer 220 is formed on the non-cell region M of the semiconductor substrate, and a semiconductor layer 230 having a first-conductivity-type doping is formed on the isolation dielectric layer 220. In one embodiment, the semiconductor layer 230 is a first-conductivity-type polysilicon layer. The semiconductor layer 230 may also be made of other polycrystalline semiconductor materials. The semiconductor layer 230 has a thickness of H2 about 4000 Å. In one embodiment, the isolation dielectric layer 220 has a thickness H3 ranging from 1000 Å to 2000 Å, optionally about 1500 Å. In one embodiment, the isolation dielectric layer 220 is a silicon oxide layer. In a specific embodiment, when the isolation dielectric layer 220 is a silicon oxide layer, and the semiconductor layer 230 is a polysilicon layer, the method for forming the silicon oxide layer on the non-cell region of the semiconductor substrate 210 and forming a first-conductivity-type polysilicon layer on the silicon oxide layer may specifically includes: forming a thermal oxidation layer on the semiconductor substrate 210 by a thermal oxidation process, depositing a polysilicon layer on the thermal oxide layer by a deposition process, performing a first-conductivity-type doping on the polysilicon layer by a doping process to form the first-conductivity-type polysilicon layer, etching away the poly silicon in the cell region by first photolithography and etching processes and retaining the polysilicon in the non-cell region, etching away the thermal oxide layer in the cell region by a second etching process and retaining the thermal oxide layer in the non-cell region. In the second etching process, the thermal oxide layer may be etched for a second time by using the polysilicon layer as a mask, thus one photolithography process can be omitted. Process steps of forming an isolation dielectric layer on the semiconductor substrate of the non-cell region, and forming a semiconductor layer having a first-conductivity-type doping on the isolation dielectric layer are not limited thereto. In other embodiments, photolithography and etching processes may be performed first, followed by a doping process.

In step S220, a first-conductivity-type well implantation is performed on the semiconductor substrate by using the semiconductor layer and the isolation dielectric layer as masks, and a well region is formed in the cell region of the semiconductor substrate.

As shown in FIG. 3b, the first-conductivity-type well implantation is performed on the semiconductor substrate 210 by using the semiconductor layer 230 and the isolation dielectric layer 220 as masks, and a well region 213 is formed in the cell region of the semiconductor substrate. In one embodiment, the isolation dielectric layer 220 and the semiconductor layer 230 have a total thickness H2+H3 ranging from 5000 Å to 6000 Å. The thickness may prevent well implantation particles from entering the non-cell region of the semiconductor substrate in during the well implantation. In one embodiment, a dose of the first-conductivity-type doping of the semiconductor layer is at least one order of magnitude greater than a dose of the first-conductivity-type well implantation of the semiconductor substrate. The dose of the first-conductivity-type well implantation is no more than 2E13/cm², which may be 5E12/cm² to 2E13/cm². The dose of the first-conductivity-type doping of the semiconductor layer 230 is no less than 4E14/cm², which may be 4E14/cm² to 8E14/cm². That is, the dose of the first-conductivity-type doping of the semiconductor layer 230 is at least ten times of that of the first-conductivity-type well implantation. When the first-conductivity-type well implantation is performed using the semiconductor layer 230 and the isolation dielectric layer 220 as masks, first-conductivity-type well implantation particles have little effect on the semiconductor layer. When the protection structure has a relatively high requirement on the accuracy of a concentration of the first-conductivity-type doping of the semiconductor layer, a doping dose may be appropriately reduced in consideration of the influence of a subsequent well implantation process when the first-conductivity-type doping of the semiconductor layer is performed.

In one embodiment, when the work structure is a VDMOS transistor, prior to the well implantation process, the method further includes a step of forming a trench in the cell region, forming a gate oxide layer on an inner wall of the trench and filling the trench with gate polysilicon. As shown in FIG. 3b, a plurality of trenches are formed on the cell region of the semiconductor substrate 210 by photolithography and etching processes, a gate oxide layer 212 is formed on inner walls of the trenches by a thermal oxide process, a layer of polysilicon is deposited by a deposition process. The trenches are filled with the polysilicon, and the polysilicon outside the trenches is removed by an etch-back process, and the polysilicon inside the trenches is retained to form gate polysilicon 122.

In step S230, the well region is doped to form the work structure in the cell region, and the semiconductor layer is doped to form the protection structure on the non-cell region.

The work structure is formed in the semiconductor substrate 210 by using the semiconductor substrate of the cell region as a base. The protection structure is formed on the semiconductor substrate 210 by using the semiconductor layer on the semiconductor substrate of the non-cell region as a base. After step S220 of forming the semiconductor layer 230 and the well region 213, the work structure is formed in the cell region and the protection structure is formed on the non-cell region by processes such as doping.

In step S240, an interlayer dielectric layer is formed on the work structure and the protection structure, a contact hole is formed in the interlayer dielectric layer, a metal interconnection layer connected to the contact hole is formed on the interlayer dielectric layer, and the work structure and the protection structure are connected by the metal interconnection layer and the contact hole.

The work structure and the protection structure are formed by step S230. The protection structure is formed in the semiconductor layer 230, and the work structure is formed in the cell region of the semiconductor substrate 210. As shown in FIG. 3d, after the work structure and the protection structure are formed, there is a need to deposit an interlayer dielectric layer 240, a contact hole is formed in the interlayer dielectric layer 240, various electrodes of the work structure and the protection structure are extracted through the contact hole. A metal interconnection layer connected to the contact hole is then deposited on the interlayer dielectric layer, and the work structure and the protection structure are connected by the metal interconnection layer and the contact hole.

Step S230 and step S240 are described with an example in which the work structure is a VDMOS transistor and the protection structure is a diode. The semiconductor substrate has a second conductivity type.

In step S230, the step of doping the well region to form the work structure in the cell region and doping the semiconductor layer to form the protection structure on the non-cell region specifically includes:

performing a second-conductivity-type doping to the well region to form a source region, and performing a second-conductivity-type doping to a partial region of the semiconductor layer to form a first-conductivity-type semiconductor structure and a second-conductivity-type semiconductor structure that are parallel to each other.

As shown in FIG. 3c, the well region 213 is doped to form a source region 214, and a second-conductivity-type doping is performed to a partial region of the semiconductor layer to convert a first-conductivity-type semiconductor in the partial region into a second-conductivity-type semiconductor, so as to enable the semiconductor layer to form a first-conductivity-type semiconductor structure 231 and a second-conductivity-type semiconductor structure 232 that are parallel to each other. The first-conductivity-type semiconductor structure 231 is a region in the semiconductor layer where no second-conductivity-type doping is performed. The second-conductivity-type semiconductor structure 232 is a region in the semiconductor layer where the second-conductivity-type doping is performed. The parallel first-conductivity-type semiconductor structure 231 and the second-conductivity-type semiconductor structure 232 form a PN junction. In one embodiment, still referring to FIG. 3c, the semiconductor layer forms a plurality of first-conductivity-type semiconductor structures 231 and a plurality of second-conductivity-type semiconductor structures 232 that are equal in number. The first-conductivity-type semiconductor structures 231 and the second-conductivity-type semiconductor structures 232 are arranged alternately. The first electrode and the second electrode of the diode are respectively extracted from the outermost first-conductivity-type semiconductor structure 231 and the outermost second-conductivity-type semiconductor structure 232, thereby forming a plurality of series PN junctions.

In one embodiment, the step of performing the second-conductivity-type doping to the well region to form the source region, and performing the second-conductivity-type doping to the partial region of the semiconductor layer specifically includes: forming a doping window on the well region and the semiconductor layer by sharing a mask plate, and performing a second-conductivity-type doping to the well region and the semiconductor layer simultaneously. A doping window is formed above the cell region and on a part of the semiconductor layer by sharing the mask plate, and the second-conductivity-type doping is performed to the well region and part of the semiconductor layer simultaneously, such that process steps can be saved.

In step S240, the step of forming the interlayer dielectric layer on the work structure and the protection structure, forming the contact hole in the interlayer dielectric layer, forming the metal interconnection layer connected to the contact hole on the interlayer dielectric layer, and connecting the work structure and the protection structure by the metal interconnection layer and the contact hole specifically includes:

forming the interlayer dielectric layer above the source region, the trench, and the first-conductivity-type semiconductor structure and the second-conductivity-type semiconductor structure, forming a first contact hole on the interlayer dielectric layer above the source region and extracting a source connected to the source region, forming a second contact hole on the interlayer dielectric layer above the trench and extracting a gate connected to the gate polysilicon, forming a third contact hole on the interlayer dielectric layer above the first-conductivity-type semiconductor structure and extracting a first electrode of the diode, forming a fourth contact hole on the interlayer dielectric layer above the second-conductivity-type semiconductor structure and extracting a second electrode of the diode, forming the metal interconnection layer on the interlayer dielectric layer, and connecting the first electrode to the gate and the second electrode to the source.

As shown in FIG. 3d, the interlayer dielectric layer 240 is deposited on the source region, the trench, the first-conductivity-type semiconductor structure, and the second-conductivity-type semiconductor structure. A first contact hole 251 is formed in the interlayer dielectric layer 240 above the source region 214, and a source connected to the source region 214 is extracted. A second contact hole is formed in the interlayer dielectric layer 240 above the trench, and a gate connected to the gate polysilicon 212 is extracted. A third contact hole 253 is formed in the interlayer dielectric layer above the first-conductivity-type semiconductor structure 231 and a first electrode of the diode is extracted. A fourth contact hole 254 is formed on the interlayer dielectric layer 240 above the second-conductivity-type semiconductor structure 232, and a second electrode of the diode is extracted. The metal interconnection layer is formed on the interlayer dielectric layer 240. The metal interconnection layer includes a first metal strip 261 connected to the first contact hole, a second metal strip (not shown) connected to the second contact hole, a third metal strip 263 connected to the third contact hole 253, and a fourth metal strip 264 connected to the fourth contact hole 254. The first electrode is connected to the gate and the second electrode is connected to the source by the metal interconnection layer and the contact hole. In one embodiment, the first through hole 251 through which the source is extracted penetrates the source region 214 and extends to the well region 213. The third contact hole 253 through which the first electrode of the diode is extracted penetrates the first-conductivity-type semiconductor structure 231 and stops on the isolation dielectric layer 220. The fourth contact hole 254 through which the second electrode of the diode is extracted penetrates the second-conductivity-type semiconductor structure 232 and stops on the isolation dielectric layer 220. At the same time, a drain is formed on one side of the semiconductor substrate 210 away from the interlayer dielectric layer, thereby completing a parallel connection of the VDMOS transistor and the diode, and an electrostatic protection function for the VDMOS transistor is achieved using the diode.

In one embodiment, the semiconductor substrate includes a semiconductor base and an epitaxial layer grown from the semiconductor base. In one embodiment, the first conductivity type may be P-type, and the second conductivity type may be N-type. Alternatively, the first conductivity type may be N-type, and the second conductivity type may be P-type. When the first conductivity type is P-type, the VDMOS transistor formed with the above method is an N-type VDMOS transistor, the first electrode in the formed diode is an anode, and the second electrode is a cathode. When the first conductivity type is N-type, the VDMOS transistor formed with the above method is a P-type VDMOS transistor, the first electrode in the formed diode is a cathode, and the second electrode is an anode. The VDMOS transistor is specifically taken as a work structure in the above embodiment. In other embodiments, the work structure may also be a lateral double-diffused metal-oxide-semiconductor field-effect transistor (referred hereinafter as LDMOS transistor) or other semiconductor devices with a well implantation process. Solutions of realizing self-alignment well implantation by replacing field oxide with the isolation dielectric layer and the semiconductor layer in the protection structure as masks during well implantation all fall within the protection scope of the present disclosure.

According to the above method for manufacturing the semiconductor device, prior to performing well implantation to the cell region N of the semiconductor substrate 210, the isolation dielectric layer 220 and the semiconductor layer 230 are formed in the non-cell region M in advance, and the well implantation is performed on the semiconductor substrate 210 by using the isolation dielectric layer 220 and the semiconductor layer 230 together as self-alignment masks, so as to form the well region in the cell region N. The non-cell region M is not affected by well implantation due to a shielding effect of the isolation dielectric layer 220 and the semiconductor layer 230. In the conventional technology, the protection structure on the non-cell region is formed on the field oxide, and the field oxide is used as a self-alignment mask. The thickness h1 of the field oxide is thicker. In the present disclosure, the protection structure on the non-cell region is formed on the isolation dielectric layer 220. Since the isolation dielectric layer 220 and the semiconductor layer 230 that forms the protection structure are used as the self-alignment masks, the isolation dielectric layer 220 and the semiconductor layer 230 can serve as self-alignment masks as long as they have a particular thickness as a whole. That is, the thickness H3 of the isolation dielectric layer 220 may be thinner, and the thickness H3 of the isolation dielectric layer is less than the thickness h1 of the field oxide, while the thickness of the semiconductor layer remains constant, i.e., H2=h2, such that a height of a step formed by the protection structure on the non-cell region and the work structure in the cell region is decreased. When the thickness of the interlayer dielectric layer above the cell region is constant, i.e., D2=d2, the thickness of the interlayer dielectric layer above the protection structure on the non-cell region in the present disclosure is increased, i.e., D1>d1, such that an isolation effect of the interlayer dielectric layer to protection structure is enhanced.

Technical features of the above embodiments may be combined randomly. To make descriptions brief, not all possible combinations of the technical features in the embodiments are described. Therefore, as long as there is no contradiction between the combinations of the technical features, they should all be considered as scopes disclosed in the specification.

The above embodiments only describe several implementations of the present application, which are described specifically and in detail, and therefore cannot be construed as a limitation on the patent scope of the present application. It should be pointed out that those of ordinary skill in the art may make various changes and improvements without departing from the ideas of the present application, all of which shall fall within the protection scope of the present application. Therefore, the patent protection scope of the present application shall be subject to the appended claims.

What is claimed is:

1. A method for manufacturing a semiconductor device, the semiconductor device comprising a work structure and a protection structure configured to protect the work structure, the method comprising:
providing a semiconductor substrate comprising a cell region and a non-cell region, forming an isolation dielectric layer on the non-cell region of the semiconductor substrate, and forming a semiconductor layer having a first-conductivity-type doping on the isolation dielectric layer;
performing a first-conductivity-type well implantation to the semiconductor substrate by using the semiconductor layer and the isolation dielectric layer as masks, and forming a well region in the cell region of the semiconductor substrate;
doping the well region to form the work structure in the cell region, and doping the semiconductor layer to form the protection structure on the non-cell region; and
forming an interlayer dielectric layer on the work structure and the protection structure, forming a contact hole in the interlayer dielectric layer, forming a metal interconnection layer connected to the contact hole on the interlayer dielectric layer, the work structure and the protection structure being connected by the metal interconnection layer and the contact hole.

2. The manufacturing method according to claim 1, wherein a dose of the first-conductivity-type doping of the semiconductor layer is at least one order of magnitude greater than a dose of the first-conductivity-type well implantation of the semiconductor substrate.

3. The manufacturing method according to claim 2, wherein the dose of the first-conductivity-type doping is no less than 4E14/cm² and the dose of the first-conductivity-type well implantation is no more than 2E13/cm².

4. The manufacturing method according to claim 1, wherein the isolation dielectric layer has a thickness ranging from 1000 Å to 2000 Å.

5. The manufacturing method according to claim 4, wherein a total thickness of the isolation dielectric layer and the semiconductor layer ranges from 5000 Å to 6000 Å.

6. The manufacturing method according to claim 1, wherein the isolation dielectric layer is a silicon oxide layer.

7. The manufacturing method according to claim 6, wherein the semiconductor layer is a first-conductivity-type polysilicon layer.

8. The manufacturing method according to claim 1, wherein the cell region is located at a center position of the semiconductor substrate, and the non-cell region is located on a periphery of the semiconductor substrate and surrounds the cell region.

9. The manufacturing method according to claim 1, wherein the work structure is a VDMOS transistor, and prior to the step of performing the first-conductivity-type well implantation to the cell region of the semiconductor substrate, the method further comprises:
forming a trench in the cell region, forming a gate oxide layer on an inner wall of the trench, and filling the trench with gate poly-silicon.

10. The manufacturing method according to claim 9, wherein the protection structure is a diode, and the semiconductor substrate has a second conductivity type;
the step of doping the well region to form the work structure in the cell region, and doping the semiconductor layer to form the protection structure on the non-cell region specifically comprises:
performing a second-conductivity-type doping to the well region to form a source region, and performing a second-conductivity-type doping to a partial region of the semiconductor layer to form a first-conductivity-type semiconductor structure and a second-conductivity-type semiconductor structure that are parallel to each other;
the step of forming the interlayer dielectric layer on the work structure and the protection structure, forming the contact hole in the interlayer dielectric layer, forming the metal interconnection layer on the interlayer dielectric layer connected to the contact hole, the work structure and the protection structure being connected by the metal interconnection layer and the contact hole specifically comprises:
forming the interlayer dielectric layer on the source region, the trench, and the first-conductivity-type semiconductor structure and the second-conductivity-type semiconductor structure, forming a first contact hole on the interlayer dielectric layer above the source region and extracting a source connected to the source region, forming a second contact hole on the interlayer dielectric layer above the trench and extracting a gate connected to the gate polysilicon, forming a third contact hole on the interlayer dielectric layer above the first-conductivity-type semiconductor structure and extracting a first electrode of the diode, forming a fourth contact hole on the interlayer dielectric layer above the second-conductivity-type semiconductor structure and extracting a second electrode of the diode, forming the metal interconnection layer on the interlayer dielectric layer, connecting the first electrode to the gate, and connecting the second electrode to the source.

11. The manufacturing method according to claim 10, wherein the step of performing the second-conductivity-type doping to the well region to form the source region, and performing the second-conductivity-type doping to the partial region of the semiconductor layer specifically comprises:
forming a doping window on the well region and the semiconductor layer by sharing a mask plate, and performing the second-conductivity-type doping to the well region and the semiconductor layer simultaneously.

12. The manufacturing method according to claim 10, wherein the first contact hole penetrates the source region and extends into the well region.

13. The manufacturing method according to claim 10, wherein the semiconductor layer forms a plurality of first-conductivity-type semiconductor structures and a plurality of second-conductivity-type semiconductor structures, a number of the first-conductivity-type semiconductor structures is equal to a number of the second-conductivity-type semiconductor structures, the first-conductivity-type semiconductor structures and the second-conductivity-type semiconductor structures are arranged alternately, and the first electrode and the second electrode of the diode are respectively extracted from an outermost first-conductivity-type semiconductor structure and an outermost second-conductivity-type semiconductor structure.

14. The manufacturing method according to claim 10, wherein a drain is formed on one side of the semiconductor substrate away from the interlayer dielectric layer.

15. The manufacturing method according to claim 7, wherein the step of forming the isolation dielectric layer on the semiconductor substrate of the non-cell region, and forming the semiconductor layer having the first-conductivity-type doping on the isolation dielectric layer specifically comprises:
forming a thermal oxidation layer on the semiconductor substrate by a thermal oxidation process;
depositing a polysilicon layer on the thermal oxide layer by a deposition process;
performing a first-conductivity-type doping to the polysilicon layer by a doping process;
etching away the polysilicon layer in the cell region by a first photolithography and an etching processes, and retaining the polysilicon layer in the non-cell region; and
etching away the thermal oxide layer on the cell region by a second etching process by using the retained polysilicon layer as a mask, and retaining the thermal oxide layer in the non-cell region, the retained thermal oxide layer and the retained polysilicon layer being the isolation dielectric layer and the semiconductor layer, respectively.
